(19) United States
(12) Patent Application Publication
(10) Pub. No.: US 2007/0284134 A1
(43) Pub. Date: Dec. 13, 2007

(54) TEXTILE SYSTEM WITH A PLURALITY OF ELECTRONIC FUNCTIONAL ELEMENTS

(75) Inventors: Robert Sliepen, Muenster (DE); Henning Gerder, Luebeck (DE)

Correspondence Address: MCGLEW & TUTTLE, PC, P.O. BOX 9227, SCARBOROUGH STATION, SCARBOROUGH, NY, 10510-9227, US

(73) Assignee: DRAEGER MEDICAL AG & CO. KG, Luebeck (DE)

(21) Appl. No.: 11/686,634

(22) Filed: Mar. 15, 2007

(30) Foreign Application Priority Data
Apr. 13, 2006 (DE) 10 2006 017 540.9

(51) Int. Cl. H05K 1/09

(52) U.S. Cl. 174/251

(57) ABSTRACT

A textile system is provided with a flat textile part and with a plurality of electronic functional elements. The functional elements are arranged on the textile part. A process for data transmission in a textile system is also presented and described. The textile part has a first conductor and a second conductor. The conductors are flat and extend on the textile part. The electronic functional elements are connected to the first conductor and to the second conductor.

### CROSS REFERENCE TO RELATED APPLICATIONS

This application claims the benefit of priority under 35 U.S.C. § 119 of DE 10 2006 017 540.9 filed Apr. 13, 2006, the entire contents of which are incorporated herein by reference.

### FIELD OF THE INVENTION

The present invention pertains to a textile system with a flat textile part and with a plurality of electronic functional elements, which are arranged on the textile part, as well as to a process for data transmission in a textile system.

### BACKGROUND OF THE INVENTION

So-called “intelligent” textiles or pieces of clothing, summarily called “textile systems,” have acquired ever-increasing significance in medical engineering. Functional elements, which are designed as measuring devices and with which it is possible to detect a great variety of data, are integrated here in the textile system. At the same time, the flexibility, tactility and breathability of the fabric can be utilized, so that the measuring devices can ultimately be worn by the patient as comfortably as possible. However, it shall be pointed out that the “intelligence” of the textiles does not arise, e.g., from the textile components, but it originates from the electronics integrated therein.

A textile system, in which a plurality of electronic functional elements are arranged on a textile part, is known from U.S. Pat. No. 6,729,025, wherein the functional elements may be designed as flexible printed circuit boards on which components are, in turn, arranged. The problem is at first that the flexibility of a printed circuit board is limited to the flexibility thereof, whereas stretchability cannot be achieved without further design measures, for example, a meander-like structure.

Furthermore, it is disclosed in U.S. Pat. No. 6,729,025 that the plurality of functional elements may be connected to one another via separate conductors, but the need for the presence of electrically conductive fibers as a part of the fabric of the textile parts shall be avoided.

A textile system with a textile part, which has a plurality of electrically conductive fibers, so that electric functional elements can be connected to one another via conductive fibers, is, in turn, known from U.S. Pat. No. 6,210,771. However, it is disadvantageous that only individual fibers must be contacted to build up a connection between the functional elements and other fibers may optionally be interrupted. As a result, the positions of the functional elements cannot be changed as desired, and it is not possible to additionally install additional functional elements on such a system which already exists without great effort.

It may be necessary, especially if such a textile system is used to detect data, such as an electrocardiogram signal or pulse and temperature at a patient by means of the functional elements, to adapt the textile system individually to the patient, and the type, number and position of the functional elements shall, in particular, be able to be easily varied.

It is also necessary now for the system for contacting the functional elements at the conductors contained in the textile part to be reliable. In addition, it should be insensitive to pulling forces especially at right angles to the plane of the textile part.

### SUMMARY OF THE INVENTION

Based on this state of the art, the basic object of the present invention is to make available a textile system with a textile part for a plurality of functional elements as well as a process for data transmission in a textile part, which makes it possible to arrange the functional elements flexibly on the textile part.

In terms of the device, this object is accomplished by the textile part having a first conductor and a second conductor, by the conductors having a flat shape and extending on the textile part, and by the electronic functional elements being connected to the first conductor and to the second conductor.

A textile part will hereinafter be defined as a flat, textile material, which may have the form of, among other things, a piece of clothing, for example, a T-shirt, a pullover or the like. However, it is also possible that the textile part is simply only a flat piece of textile, which does not have a specially adapted shape. A “functional element” may be defined in the sense of the present invention, on the one hand, as measuring devices, with which patient data such as pulse and temperature are detected. On the other hand, this term also covers transmitting and receiving means, with which patient data are transmitted to a base station.

Due to the two flat conductors, which extend at least on one part of the textile part, it is possible to provide a textile system with nearly any desired number of different functional elements and to also arrange these as desired, because the individual functional elements can communicate with one another because of the two conductors by means of a bus system and a corresponding data transmission process. One of the two conductors can now be used for data transmission and the other as a reference potential.

In case of a design with two conductors, the functional elements can be supplied with power via the two conductors. However, it is also conceivable that the functional elements have a power source of their own, such as a rechargeable battery. Besides, in addition to the two conductors for the data transmission, additional conductors may be present for power supply in the textile part.

The need to provide separate connections between the functional elements is eliminated due to the two conductors. As a result, a more flexible textile system is obtained, on the whole, which can be individually adapted to the needs of the particular patient in a simple manner, especially in case of use for patient data detection.

The first conductor and the second conductor are preferably designed as layers in the textile part, which are electrically insulated against one another and extend in parallel. The layers may be designed as a fabric of conductive fibers now. This has the advantage that the necessary contacting of a functional element can be brought about in a simple manner by the conductor located close to the functional element being pushed through and the conductor located under it being at least contacted.

In another preferred manner, an insulating layer is arranged between the conductors in order to ensure that no short-circuit will develop between the conductors, even if the textile part is greatly deformed.

In an especially preferred embodiment, the insulating layer may be impermeable to water, but permeable to water vapor and air. As a result, the conductors are prevented, on the one hand, from being short-circuited by moisture. On the other hand, air can reach the patient's body, so that the textile part can be worn comfortably.

Furthermore, the first and second conductors may be strip-shaped, so that they extend, for example, in a meandering pattern along the textile part. The conductors may have a nearly linear cross section now, being in contact with the textile part by the flat side. The loadability of the conductors can be increased by such an embodiment in case of deformations. To ensure, furthermore, that the conductors are protected against external effects, it is, furthermore, preferred to surround the conductors with a jacket.

As an alternative, the first conductor may have a plurality of first fibers and the second conductor a plurality of second fibers, the first fibers extending in a first direction in parallel to one another through the textile part and the second fibers in a second direction. In an especially preferred manner, the directions extend at right angles to one another. Such a grid formed from the two conductors has the advantage that the surfaces of the conductors, which surfaces are located opposite each other, are small and the capacitive loss in the system is likewise low. Yet, the contacting of the functional elements can be brought about in the manner described above at the intersections between the first and second conductors. In addition, such a grid-like structure is deformable in a highly flexible manner, is lightweight and breathable.

The textile system according to the present invention is preferably provided with a plurality of terminals in the textile part, the electronic functional elements have contacts, and the terminals and contacts are designed for detachable connection to one another. The functional elements can be contacted with one of the terminals in a simple manner in this embodiment, so that a textile system can be easily adapted to the particular needs, for example, those of a patient. The terminals or contacts may be designed, in particular, such that they have an elastic locking element, which meshes with the contact or terminal in case of connection to a contact or terminal in order to lock the electronic functional element on the textile part. It is thus ensured when a functional element is contacted that this element is also mechanically rigidly connected to the textile part. The terminals have a first terminal element and a second terminal element, the first terminal element being connected to the first conductor and the second terminal element to the second conductor. As a result, a functional element is connected by a single terminal to both the first conductor and the second conductor.

In a preferred embodiment of the system, one functional element has a rechargeable battery, and one functional element is designed as a power supply unit, by which a supply voltage is applied to the first conductor and the second conductor. It is possible in this manner to charge the batteries of the other functional elements by the functional element that is designed as a charger and can be connected, the other functional elements being switched over to a charge mode if the supply voltage is present on the first and second conductors.

Furthermore, it is preferred if the first conductor and the second conductor are completely severed along a separation line, so that the first conductor and the second conductor have two separate areas. So-called subnetworks, which are separated from one another, can thus be embodied on the textile part. In case the textile part is a piece of clothing, subnetworks can be created, which extend over the trunk, on the one hand, and over the arms, on the other hand. In another preferred manner, a bridging element is provided, and the bridging element connects the first and second areas of the first conductor and the first and second areas of the second conductor. It is especially preferred now for the bridging element to be designed as an optoelectronic coupler. It can be achieved as a result that the subnetworks are decoupled from one another, which may be necessary concerning safety engineering requirements, e.g., for defibrillation protection.

In another preferred embodiment, the textile system has transmission elements, which are provided on the first and second conductors and which may be designed as a coil or an antenna. Data can be transmitted by means of these transmission elements from one textile system to a second one, which is in contact with the first textile system. This is of interest when a patient carries, for example, a plurality of pieces of clothing connected to functional elements, and these are to exchange data with one another.

Furthermore, the above object is accomplished by a process for data transmission in a textile system with a textile part, with a plurality of electronic functional elements, with a master functional element and with a first conductor and a second conductor, the conductors extending on the textile part, the functional elements and the master functional element can be connected to the first conductor and the second conductor, and the functional elements present in the textile system being detected by the master functional element, time slots for transmitting the measured data being assigned to the functional elements by the master functional element, and the functional elements transmitting measured data via the first and second conductors to the master functional element in the time slots assigned to them.

The communication with the textile system according to the present invention may take place, in principle, either in such a way that all functional elements are considered to enjoy equal rights (peer-to-peer network), or the communication takes place on the basis of a master-slave architecture, in which case a master functional element, which assumes the control, must be provided. If the textile system is designed as a master-slave system, this does, however, offer the advantage that different data rates and speeds can be operated on a single data bus.

The functional elements present in the textile system are first detected by the master functional element by the process according to the present invention, the master functional element receiving the type of functional element and thus the measured variable determined by the particular functional element.

Once all the functional elements present in the textile system have been detected, the master functional element assigns time slots, in which the functional elements transmit measured data to the master functional element via the first conductor and the second conductor, to the functional elements as a function of the particular detected type of measured variable.

Since the time slots for each functional element are thus set in advance, the functional elements can be switched to an energy-saving mode (sleep mode) between the time slots for transmitting data, so that the overall energy consumption in the system can be reduced. In addition, the assignment of the time slots opens up the possibility of assigning time slots in short time intervals to those functional elements whose measured data display more rapid variations. For example, time slots that have a short time interval between them may thus be assigned to a pulse sensor, whereas time slots that have a longer time interval may be assigned to a temperature sensor. The energy consumption in the textile system can thus be further reduced, because the functional elements “wake up” from the energy-saving mode only when this is also necessary because of the type of the detected measured variable.

The functional elements preferably have an unambiguous identification, and the detection of the functional elements comprises the following steps:
Sending of an initialization command by the master functional element via the first conductor and the second conductor to the functional elements, and
sending of a response signal via the first conductor and the second conductor by each of the functional elements after a waiting time, the response signal containing the identification and the waiting time being set by the identification.

By setting the waiting time via the unambiguous identification, it can be ensured in a simple manner that the response signals to the master functional element are separated from each other by time, so that the functional elements, which are arranged on the textile part, can be selected as desired.

In another preferred manner, the identification is formed by a numerical value, the waiting time being proportional to the numerical value. The initialization command may comprise a delay factor now, and the waiting time corresponds to the product of the numerical value times the delay factor. The delay factor offers the master functional element the possibility of changing the delay factor in a suitable manner in case response signals from a plurality of functional elements overlap, so that the response signals are subsequently separated from one another.

To enable the master functional element to determine the type of functional element before it assigns the time slots, it is, furthermore, preferable for the identification to comprise a type identification and an individual identification.

In another preferred exemplary embodiment of the process according to the present invention, alarm time slots are set by the master functional element, so that the functional elements can send alarm signals outside the time slots assigned to them. Alarm time slots are advantageous because functional elements may optionally detect patient data that are extraordinarily important and for which a deviation from a set point or the appearance of a critical value must be processed by the system as rapidly as possible.

Finally, polling time slots may be set by the master functional element in another preferred manner, so that the master functional element can send polling signals via the conductors to the functional elements during the polling time slots, so that the master functional element can directly address individual functional elements.

The various features of novelty which characterize the invention are pointed out with particularity in the claims annexed to and forming a part of this disclosure. For a better understanding of the invention, its operating advantages and specific objects attained by its uses, reference is made to the accompanying drawings and descriptive matter in which preferred embodiments of the invention are illustrated.

### BRIEF DESCRIPTION OF THE DRAWINGS

In the drawings:

FIG. 1 is a cross section of a part of a first exemplary embodiment of a textile system according to the present invention;

FIG. 2 is a top view of a part of a second exemplary embodiment of a textile system according to the present invention;

FIG. 3 is a top view of a third exemplary embodiment designed as a piece of clothing;

FIG. 4 is a cross section of a part of the third exemplary embodiment; and

FIG. 5 is a time chart of the course of data transmission in a textile system according to the present invention.

### DESCRIPTION OF THE PREFERRED EMBODIMENTS

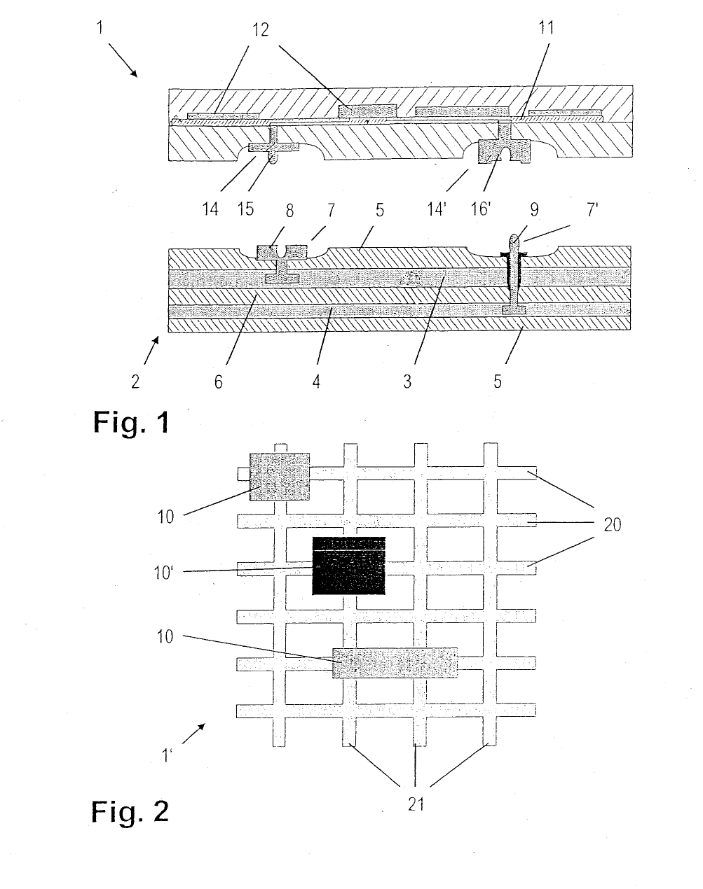

Referring to the drawings in particular, the first exemplary embodiment of a textile system 1 according to the present invention, whose cross section is shown in FIG. 1, comprises a textile part 2, which has a first conductor 3 and a second conductor 4. A textile part 2 according to the present invention is defined as a flat textile material, which may have, among other things, the form of a piece of clothing, for example, a T-shirt, a pullover or the like. However, it is also possible that the textile part 2 is simply only a flat piece of textile that does not have any specially selected shape.

The conductors 3, 4 are of a flat design in this exemplary embodiment, which is a preferred exemplary embodiment in this respect, and extend in parallel to one another along the textile part 2 between two cover layers 5. The conductors 3, 4 are each designed here as a layer, between which an insulating layer 6 extends, in turn. The conductors 3, 4 may extend, on the one hand, as a closed layer over the entire surface of the textile part 2. However, it is also conceivable, on the other hand, that the conductors 3, 4 are designed as strips extending in parallel one on top of another with a flat cross section, which extend, for example, in a meandering pattern along the textile part 2. Such a strip-shaped design is associated with the advantage that the conductors 3, 4 can better absorb tensile stresses, which are exerted on the textile part 2. In case of a strip-shaped embodiment of the conductors 3, 4, the latter may be surrounded by a film-like jacket, not shown, in order to better protect the conductors 3, 4 against external effects such as moisture. The material of the conductors 3, 4 may be designed, among other things, as a fabric of conductive fibers.

The insulating layer 6 is designed in this embodiment as a semipermeable membrane, which is impermeable to water but permeable to water vapor and air. This prevents, on the one hand, the conductors 3, 4 from being short-circuited by moisture. On the other hand, air can reach the patient's body, so that the textile part 2 can be worn comfortably.

In addition, the textile part 2 has first and second terminal elements 7, 7′, which together form a terminal. The first terminal element 7 is connected to the first conductor 3 and the second terminal element 7′ to the second conductor 4. The first terminal element 7 is provided, furthermore, with an elastic locking element 8, while the second terminal element 7′ has a catch element 9. The locking element 8 is electrically connected here to the first conductor 3, while the catch element 9 is electrically connected to the second conductor 4 and is insulated against the first conductor 3. While FIG. 1 shows only a first and second terminal element 7, 7′ and consequently only one terminal, a plurality of first and second terminal elements 7, 7′ may be arranged adjacent to one another distributed over the surface of the textile part 2 and thus form a plurality of terminals.

Furthermore, the textile system 1 according to the first exemplary embodiment comprises a functional element 10, which has a flexible board 11, on which a plurality of electronic components 12 are, in turn, arranged. In addition, the functional element 10 has a digital interface in order for the functional elements 10, which are connected to the conductors 3, 4, to be able to communicate. The board 11 is surrounded by a jacket 13, by which the components 11 are shielded from the environment.

Functional elements 10 according to the present invention may be defined, for example, as measuring devices with which patient data such as pulse and temperature are detected. On the other hand, this term also covers transmitting and receiving means, with which patient data are transmitted to a base station. The functional elements 10 may have a rechargeable battery as a power supply unit. In case of the design with only two conductors 3, 4, the functional elements 10 may be supplied with power via the conductors 3, 4. However, the functional elements 10 may also have a rechargeable battery (not shown), one functional element being designed as a power supply unit, by which a supply voltage, by means of which the batteries can be charged, is applied to the conductors 3, 4. If the functional element designed as a charger is connected to the conductors and the supply voltage is applied, the other functional elements can be switched over from a normal mode of operation to a charge mode.

In addition, the functional element 10 is provided with contact elements 14, 14′, the contact element 14 having a catch element 15. The contact element 14′ is provided, by contrast, with a locking element 16′. The contact elements 14, 14′ together form a contact, which is designed for detachable connection to the terminals on the textile part 2.

When the functional element 10 is to be connected to the textile part 2 and to the conductors 3, 4 provided therein, the terminal and contact elements 7, 14 and the terminal and contact elements 7′, 14′ are caused to mesh with one another, the catch element 15 meshing with the locking element 8 and the catch element 9 with the locking element 16′, so that a “pushbutton-like” connection is obtained. The functional element 10 will thus snap in on the textile part 2 and is thus firmly connected to the latter, but it can be removed in a simple manner. In addition, the functional element 10 is electrically connected via the terminals 7, 7′ and 14, 14′ to the first and second conductors 3, 4, so that the functional element 10 can also be integrated into the data transmission.

It is possible due to the two flat conductors 3, 4, which extend between the cover layers 5 at least in one part of the textile part 2, to provide a textile system 1 with any desired number of different functional elements 10 and to arrange these at the terminal elements 7, 7′ as desired, because the individual functional elements 10 can communicate with one another because of the two conductors 3, 4 by means of a bus system and a corresponding data transmission process. One of the two conductors 3, 4 may now be used for data transmission and the other as a reference potential.

FIG. 2 shows a second example of a textile system 1′, in which the textile layers of the textile part are not shown for the sake of clarity. Contrary to the first exemplary embodiment, the conductors are not designed as continuous layers in this exemplary embodiment, but the first conductor comprises a plurality of first fibers 20 and the second conductor a plurality of second fibers 21. The first fibers 20 are electrically insulated against the second fibers 21, and the first fibers 20 extend in parallel to one another in a first direction through the textile part, while the second fibers 21 extend in parallel to one another in a second direction. The first direction extends at right angles to the second direction. On the whole, the conductors formed by the fibers 20, 21 consequently likewise extend flatly over the textile part.

The textile system 1′ has functional elements 10, 10′, the functional element 10′ being designed as a master functional element, which controls the communication between the functional elements 10 and the master functional element 10′. The functional elements 10 are connected to one of the first fibers 20 and one of the second fibers 21 each, so that a plurality of functional elements 10 can be arranged flexibly in this exemplary embodiment as well. The network- or grid-like structure of the conductors in this exemplary embodiment is associated with the advantage that the surfaces of the conductors, which surfaces are located opposite each other, are reduced compared to the first exemplary embodiment, so that the capacitive load is reduced for the data transmission. In addition, such a structure is more breathable and more lightweight.

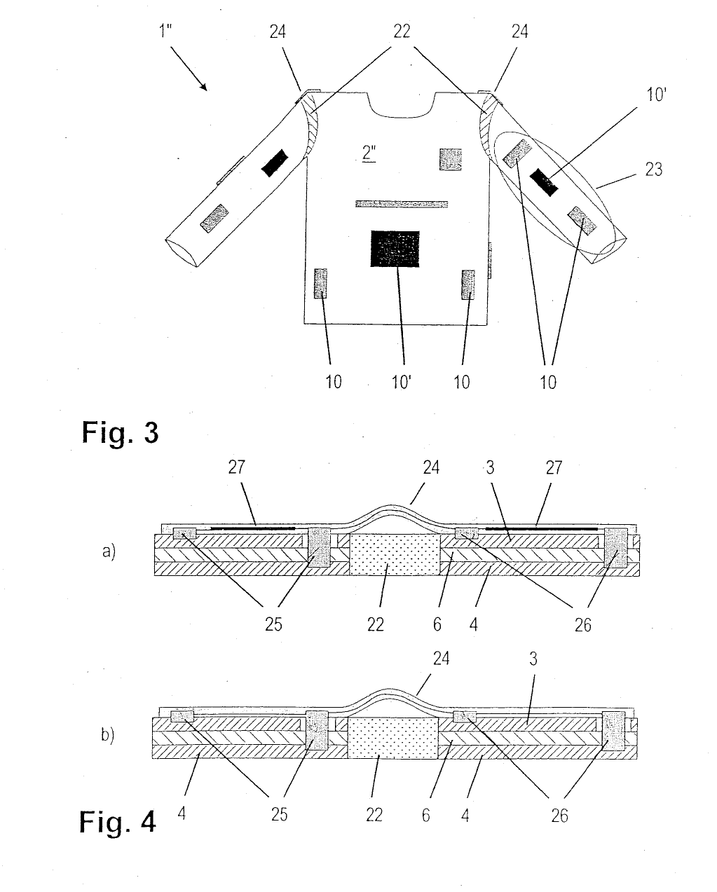

FIG. 3 shows an exemplary embodiment of a textile system 1″, in which the textile part 2″ is designed in the form of a piece of clothing, namely, a pullover. A plurality of functional elements 10, 10′, which are connected to first and second flat conductors, not shown, which extend in the textile part 2″, are, in turn, arranged on the textile part 2″. The conductors may have, for example, the same design as in the first or second exemplary embodiment, i.e., as layers extending in parallel or in a grid-like manner. As in the textile system 1′ as well, master functional elements 10′, which control the data transmission among the functional elements 10, are also provided besides functional elements 10′.

Both the first conductor and the second conductor are completely severed along two separation lines 22 in this exemplary embodiment, so that the first conductor and the second conductor have three separate areas. One of the areas extends over the trunk, while the other two extend over the arms of a patient. Subnetworks 23, which can exchange data by means of the bridging elements 24 provided at the separation lines 22, can be formed due to the separation of the conductors. The subnetworks are preferably electrically insulated against one another, and the bridging elements 24 are designed as optoelectronic couplers, so that a decoupling is established between the subnetworks and consequently the corresponding areas of the conductors.

Finally, a textile system according to the present invention may be provided with transmission elements, not shown, which are connected to the first and second conductors 3, 4 and may be designed as a coil or antenna. As a result, data can be transmitted from a first textile system 1 to a second one, which is in contact with the first textile system 1. This may be necessary when a patient wears, for example, a plurality of pieces of clothing provided with functional elements one on top of another and these are to exchange data with one another.

FIG. 4 shows two exemplary embodiments for bridging elements 24. The first example (a) is embodied as an active bridging element, while the second example (b) is a passive bridging element. The active bridging element assumes the function of a master functional element for the subnetwork, and the mode of operation will be explained below in connection with the description of the process of data transmission.

In both examples, the bridging element 24 connects areas of the first and second conductors 3, 4, which are separated from one another by the separation line 22, the separation line 22 being formed in this exemplary embodiment, which is a preferred example in this respect, by a flexible, deformable material. The bridging element 24 extends over the separation line 22 and has at its ends two terminals 25 and 26, via which the bridging element 24 is connected to the first and second conductors 3, 4. The terminals 25, 26 may have a design similar to that of the terminals 7, 7′ and 14, 14′ in FIG. 1 in order to provide a detachable connection of the bridging element 24 to the conductors and to the textile part.

Contrary to the second example (b), the first example (a) of the bridging element 24 has additional electronic components 27, which are necessary for the functions, in order for the bridging element to be able to operate as a master functional element in the subnetwork.

The process for data transmission in a textile system according to the present invention for controlling the course of data transmission over time between the functional elements 10 and the master functional element 10′ will be described in detail below.

The communication between the functional elements 10 in the textile system 1 according to the present invention may take place, on the one hand, on the basis of a master-slave architecture, in which case a master functional element must be provided, which assumes the control, or the communication takes place, on the other hand, in such a way that all functional elements 10 are considered to enjoy equal rights (peer-to-peer network). If the textile system 1 is connected as a master-slave system, this has, however, the advantage that different data rates and speeds can be operated on a single data bus.

In this exemplary embodiment, which is preferred in this respect, each of the so-called slave-master functional elements 10 has an unambiguous identification, which comprises two components. A first component is a type identification (family ID; 8 bits), which describes the type (e.g., temperature or pulse sensor), while the other component is an individual identification (likewise 8 bits long).

The slave functional elements 10 contained in the textile system 1, 1′, 1″ are first detected, and the master functional element 10′ first sends for initialization an initialization command to the slave functional elements 10 via the conductors 3, 4, the initialization command comprising an initialization sequence and a delay factor (delay multiplicator; DM).

The training sequence is used to enable the slave functional elements 10 to determine the bit length, i.e., the time period that is required for transmitting a bit.

The waiting time after which the response signal is sent arises for the particular slave functional element 10 from its identification, and the numerical value of the identification, multiplied by the delay factor, shows the number of cycles after which the sending of the response signal of the particular functional element 10 takes place. The response signal comprises the training sequence, the identification, i.e., the family ID and the individual identification, the data width (number of bits for a measured value) as well as the cycle rate at which the measured values are transmitted.

By setting the waiting time based on the unambiguous identification, it is ensured that the response signals are sent at time intervals from one another to the master functional element 10′, so that the functional elements 10, which are arranged on the textile part, can be selected as desired. If there is an overlap of response signals in time, the delay factor can be changed by the master functional element 10, and the initialization command is sent again.

After the response signals have been received, the initialization operation and consequently the detection of the functional elements 10 is concluded, and the master functional element 10′ knows the properties of the other slave functional elements 10. In the knowledge of these properties, the master functional element 10′ can then put a communications network into operation, and time slots are assigned to the slave functional elements 10 for the communication process for transmitting the measured data. In addition, polling time slots and the alarm time slots are set by the master functional element.

Alarm time slots are necessary because some functional elements 10 detect patient data that are extraordinarily important and a deviation from a set point of these measured values or the appearance of a critical value must be processed by the system as fast as possible. It is necessary for this that the data of these functional elements 10 be able to be transmitted at higher priority. The time slot process being used has alarm time slots for this purpose, which are set aside only for transmitting data with higher priority.

The polling time slots are used, on the one hand, to enable the master functional element 10′ to address the individual slave functional elements 10 separately in order to optionally check data. On the other hand, the polling time slots are used to request additional data from other functional elements 10 after an alarm reported by a slave functional element 10. In addition, the polling time slots may also be used to synchronize the slave functional elements 10 and the master functional element 10′, because an initialization command can be sent during the polling time slots.

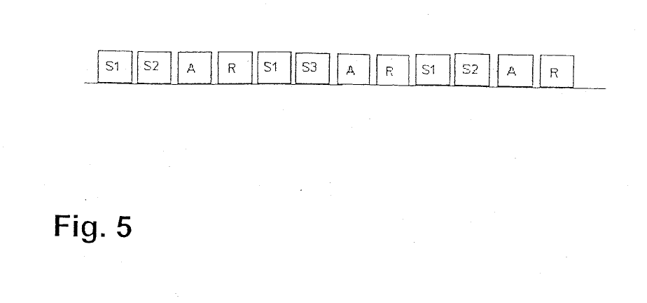

FIG. 5 shows the time structure for the communication in a textile system that comprises a master functional element 10′ and three slave functional elements 10. The time slots S1, S2 and S3 are assigned to the three slave functional elements 10 in order to transmit their measured data to the master functional element 10′. It shall be pointed out in this connection that the frequency of the time slots S1 for the first slave functional element 10 is twice as high as that for the other slave time slots S2 and S3, because the corresponding functional element shall transmit its data more frequently to the master functional element 10′.

Since the time slots S1, S2, S3 are set for each functional element 10, the functional elements 10 can be switched to an energy-saving mode (sleep mode) between the time slots S1, S2, S3 for sending the data, so that the overall energy consumption can be reduced in the textile system 1, 1′, 1″. In addition, due to the time slots S1, S2, S3 being assigned, time slots with shorter time intervals, whose measured data show more rapid variations, can be assigned to such functional elements 10. For example, time slots that have a shorter time interval between them can be assigned to a pulse sensor, whereas time slots that have a greater time interval can be assigned to a temperature sensor. The energy consumption can thus be reduced further, because the functional elements “wake up” from the energy-saving mode only when this is also necessary based on the measured variable detected.

Furthermore, polling time slots R, during which the master functional element 10′ can directly address individual slave functional elements 10, as was described above, are provided between the slave time slots S1, S2 and S3.

In addition, alarm time slots A are made available, during which the slave functional element 10 can transmit an alarm signal without having to wait for a corresponding time slot in case this functional element detects a critical value.

Such a complicated time structure is necessary to make it possible for the textile system 1 to make do with only two conductors 3, 4 for the data transmission, because, unlike in other bus designs with address and control lines, no separate back plans or power supply is present in the preferred exemplary embodiments, which makes the system especially comfortable for the patient.

The need to make available separate connections between the functional elements is eliminated due to the two conductors. As a result, a more flexible textile system is obtained, on the whole, which can be individually adapted to the needs of the particular patient in a simple manner especially when it is being used for patient data detection.

While specific embodiments of the invention have been shown and described in detail to illustrate the application of the principles of the invention, it will be understood that the invention may be embodied otherwise without departing from such principles.

What is claimed is:

1. A textile system comprising:
a flat textile part having a first flat, extending conductor and a second flat, extending conductor; and
a plurality of electronic functional elements arranged on said textile part, said electronic functional elements being connected to said first conductor and to said second conductor.

2. A textile system in accordance with claim 1, wherein said first conductor and said second conductor comprise layers in said textile part, which are electrically insulated against one another and extend in parallel.

3. A textile system in accordance with claim 2, further comprising an insulating layer arranged between said first conductor and said second conductor.

4. A textile system in accordance with claim 3, wherein said insulating layer is impermeable to water.

5. A textile system in accordance with claim 4, wherein said insulating layer is permeable to water vapor and air.

6. A textile system in accordance with claim 2, wherein said first conductor and said second conductor have a strip-shaped design.

7. A textile system in accordance with claim 6, wherein said first conductor and said second conductor are surrounded by a jacket.

8. A textile system in accordance with claim 1, wherein:
said first conductor has a plurality of first conductor fibers and said second conductor has a plurality of second conductor fibers;
said first conductor fibers extend through said textile part in parallel to one another in a first direction; and
said second conductor fibers extend through said textile part in parallel to one another in a second direction.

9. A textile system in accordance with claim 8, wherein the first direction extends at right angles to the second direction.

10. A textile system in accordance with claim 1, wherein:
a plurality of terminals are provided in said textile part;
said electronic functional elements have contacts; and
said terminals and said contacts are designed for being detachably connected to one another.

11. A textile system in accordance with claim 10, wherein said terminals or contacts have an elastic locking element, which meshes with a contact or a terminal when being connected to a contact or a terminal in order to lock said electronic functional element on said textile part.

12. A textile system in accordance with claim 10, wherein
said terminals have a first terminal element and a second terminal element; and
said first terminal element is connected to said first conductor and said second terminal element is connected to said second conductor.

13. A textile system in accordance with claim 1, wherein
one of said functional elements has a rechargeable battery; and
one of said functional element is designed as a power supply unit, by which a supply voltage is applied to said first conductor and to said second conductor.

14. A textile system in accordance with claim 1, wherein said first conductor and said second conductor are completely severed along a separation line, whereby said first conductor and said second conductor have two separate areas.

15. A textile system in accordance with claim 14, further comprising:
a bridging element connecting a first area and a second area of said first conductor and a first area and a second area of said second conductor.

16. A textile system in accordance with claim 15, wherein said bridging element comprises an optoelectronic coupler.

17. A textile system in accordance with claims 14, wherein the areas of said conductors are electrically insulated against each other.

18. A textile system in accordance with claim 1, wherein transmission elements are provided at said first and second conductors.

19. A textile system in accordance with claim 18, wherein said transmission elements are designed as a coil or an antenna.

20. A process for data transmission in a textile system, the process comprising:
providing a textile part with a plurality of electronic functional elements, with a master functional element and with a first conductor and with a second conductor;
providing the conductors extending on or in the textile part;
connecting the functional elements and the master functional element to the first conductor and to the second conductor;
detecting the functional elements present in the textile system by the master functional element;
assigning time slots to the functional elements by the master functional element for sending measured data; and
sending data, in the time slots assigned to the functional elements, as measured data by the functional elements via the first and said second conductors to the master functional element.

21. A process in accordance with claim 20, wherein the functional elements are switched to an energy-saving mode between the time slots assigned to them.

22. A process in accordance with claim 20, wherein the functional elements have an unambiguous identification and the detection of the functional elements comprises the steps of:
sending an initialization command by the master functional element via the first and second conductors to the functional elements; and
sending a response signal via the first and second conductors by each of the functional elements after a waiting time, the response signal containing the identification and the waiting time being set by the identification.

23. A process in accordance with claim 22, wherein:
the identification is formed by a numerical value; and
the waiting time is proportional to the numerical value.

24. A process in accordance with claim 23, wherein the initialization command comprises a delay factor and the waiting time corresponds to the product of the numerical value times the delay factor.

25. A process in accordance with claim 22, wherein the identification comprises a type identification and an individual identification.

26. A process in accordance with claim 20, wherein alarm slots are set by the master functional element, so that the functional elements transmit alarm signals outside the time slots assigned to them.

27. A process in accordance with claim 20, wherein:
said time slots are set by the master functional element as polling time slots; and
said master functional element sends polling signals via the conductors to the functional elements during the polling time slots.
